(19) United States
(12) Patent Application Publication
(10) Pub. No.: US 2026/0247983 A1
(43) Pub. Date: Aug. 20, 2026

(54) PROTECTION OF SEMICONDUCTOR DEVICES FROM OPTICAL SCANNING

(71) Applicant: Micron Technology, Inc., Boise, ID (US)

(72) Inventors: Paul Lambert, Mountain View, CA (US); Niccolò Izzo, Vignate (MI) (IT); David Hulton, Seattle, WA (US); Kendall Reed Davies, Seattle, WA (US)

(21) Appl. No.: 19/531,142

(22) Filed: Feb. 5, 2026

Related U.S. Application Data
(60) Provisional application No. 63/761,074, filed on Feb. 20, 2025.

(51) Int. Cl. H10W 42/40

(52) U.S. Cl. CPC H10W 42/40

(57) ABSTRACT

Methods, systems, and devices for protection of semiconductor devices from optical scanning are described. A semiconductor device may implement one or more material layers that are configured for refracting photonic emissions, which may impair an ability to use such photonic emissions for adverse analysis of the semiconductor device. For example, a semiconductor device may include one or more layers that include geometric structures that are configured to refract photonic emissions from the semiconductor device. Additionally, or alternatively, a semiconductor device may include one or more layers with different doping configurations (e.g., with different refractive indexes) that are configured to refract photonic emissions from the semiconductor device.

### CROSS REFERENCE

The present Application for Patent claims priority to U.S. Patent Application No. 63/761,074 by Lambert et al., entitled “PROTECTION OF SEMICONDUCTOR DEVICES FROM OPTICAL SCANNING,” filed February 20, 2025, which is assigned to the assignee hereof, and which is expressly incorporated by reference in its entirety herein.

### TECHNICAL FIELD

The following relates to one or more semiconductor systems, including protection of semiconductor devices from optical scanning.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports protection of semiconductor devices from optical scanning in accordance with examples as disclosed herein.

FIGS. 2A and 2B show examples of photonic emission diagrams that support protection of semiconductor devices from optical scanning in accordance with examples as disclosed herein.

FIG. 3A through 5 show examples of semiconductor devices that support protection of semiconductor devices from optical scanning in accordance with examples as disclosed herein.

FIG. 6 shows a flowchart illustrating a method or methods that support protection of semiconductor devices from optical scanning in accordance with examples as disclosed herein.

### DETAILED DESCRIPTION

In some cases, semiconductor devices (e.g., memory dies, processor dies, systems of multiple dies, dual in-line memory modules (DIMMs), memory systems, processor systems) may emit (e.g., generate, reflect, convey, convert) photonic emissions while (e.g., during, in response to) performing one or more internal operations (e.g., circuitry operations, data access operations, memory storage operations, processing operations). For example, during a memory access operation, circuitry of a semiconductor device (e.g., one or more transistors, one or more conductive lines) may generate photonic emissions associated with electronic signals (e.g., along one or more access lines) or switching (e.g., transistor switching) associated with the memory access operation. In some cases, an external device (e.g., a measurement device, an evaluation device) may be configured to detect photonic emissions of a semiconductor device, such that the external device may determine information associated with the semiconductor device. For example, an external device may be configured to apply an optical scanning method (e.g., which may implement or may not implement a separate light-producing source operating at a specified wavelength) to evaluate photonic emissions for detecting circuitry configurations, operational characteristics, or signaled information (e.g., user data) associated with a semiconductor device. In some examples, an external device may identify data or a data access pattern of a semiconductor device, or identify operations or faults of a semiconductor device, based on photonic emissions from the semiconductor device. In some examples, photonic emissions from a semiconductor device may be observed for use in adverse analysis (e.g., reverse engineering, data detection) of the semiconductor device and its internal operations, which may pose a security threat (e.g., associated with data of the semiconductor device, to a user of the semiconductor device).

In accordance with examples as described herein, a semiconductor device may implement one or more material layers (e.g., material countermeasures) that are configured for refracting photonic emissions, which may impair an ability to use such photonic emissions for adverse analysis of the semiconductor device. For example, a semiconductor device may include one or more layers (e.g., at a backside of the semiconductor device, or some other location) that include geometric structures that are configured to refract photonic emissions from the semiconductor device. The geometric structures may be physical structures formed at the layer or a layer interface to support different refracted angles of photonic emissions. Additionally, or alternatively, a semiconductor device may include one or more layers with different doping configurations (e.g., associated with different refractive indices) that are configured to refract photonic emissions from the semiconductor device. For example, a semiconductor device may include a first doping configuration in some portions of the layer and a second doping configuration at other portions of the layer, which may support different refracted angles of photonic emissions. Additionally, or alternatively, a semiconductor device may include particles (e.g., beads, spherical particles, ellipsoid particles, particles with irregular geometry) distributed in a material layer that are configured to refract photonic emissions from the semiconductor device (e.g., by way of different refractive indices). With an implementation of one or more layers that are configured to support different refracted angles of photonic emissions, an external device attempting to perform adverse analysis of a semiconductor device may be unable to determine sources of the photonic emissions. For example, differences in refractive indexes at a semiconductor device (e.g., due to geometric structures, doping configurations, particles, or combination thereof) may prevent an external device from locating aspects of internal circuitry, or identifying internal signaling or operating characteristics, that may otherwise be used to support adverse analysis of the semiconductor device, which may enhance security of the semiconductor device, among other advantages.

In addition to applicability in memory systems described herein, techniques for protection of semiconductor devices from optical scanning may be generally implemented to improve security and/or authentication features of various electronic devices and systems. As the use of electronic devices for handling private, user, or other sensitive information has become even more widespread, electronic devices and systems have become the target of increasingly frequent and sophisticated attacks. Further, unauthorized access or modification of data in security-critical devices such as vehicles, healthcare devices, and others may be especially concerning. Implementing the techniques described herein may improve the security of electronic devices and systems by preventing adverse devices from using photonic emissions from a semiconductor device for determining information about the semiconductor device, which may prevent unauthorized access to data or other information associated with the semiconductor device, among other benefits.

Features of the disclosure are illustrated and described in the context of systems and architectures. Features of the disclosure are further illustrated and described in the context of photonic emissions diagrams, semiconductor devices, and flowcharts.

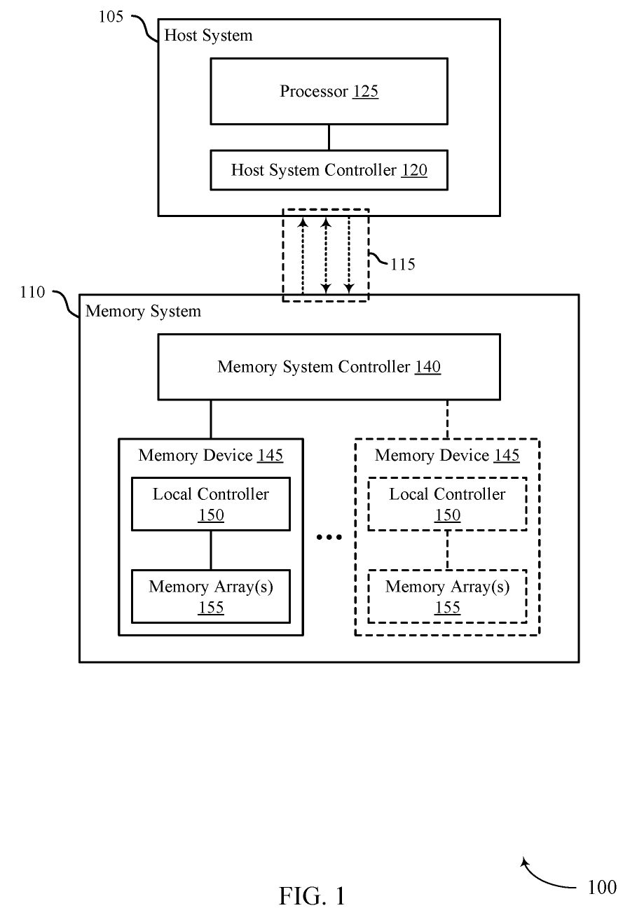

FIG. 1 shows an example of a system 100 that supports protection of semiconductor devices from optical scanning in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A semiconductor device of a system 100, or one or more components thereof (e.g., of a host system 105, of a memory system 110, of a memory device 145) may implement one or more material layers (e.g., material countermeasures) that are configured for refracting photonic emissions, which may impair an ability to use such photonic emissions for adverse analysis of the semiconductor device. For example, such a semiconductor device may include one or more layers that include geometric structures that are configured to refract photonic emissions from the semiconductor device. Additionally, or alternatively, such a semiconductor device may include one or more layers with different doping configurations (e.g., associated with different refractive indices) that are configured to refract photonic emissions from the semiconductor device. Additionally, or alternatively, such a semiconductor device may include particles (e.g., beads, spherical particles, ellipsoid particles, particles with irregular geometry) distributed in a material layer that are configured to refract photonic emissions from the semiconductor device (e.g., by way of different refractive indices). By implementing one or more of such layers that are configured to support different refracted angles of photonic emissions, an external device attempting to perform adverse analysis of a semiconductor device may be unable to determine sources of the photonic emissions. For example, differences in refractive indexes at a semiconductor device (e.g., due to the geometric structures or doping configurations) may prevent an external device from locating aspects of internal circuitry, or identifying internal signaling or operating characteristics, that may otherwise be used to support adverse analysis of the semiconductor device, which may enhance security of the semiconductor device, among other advantages.

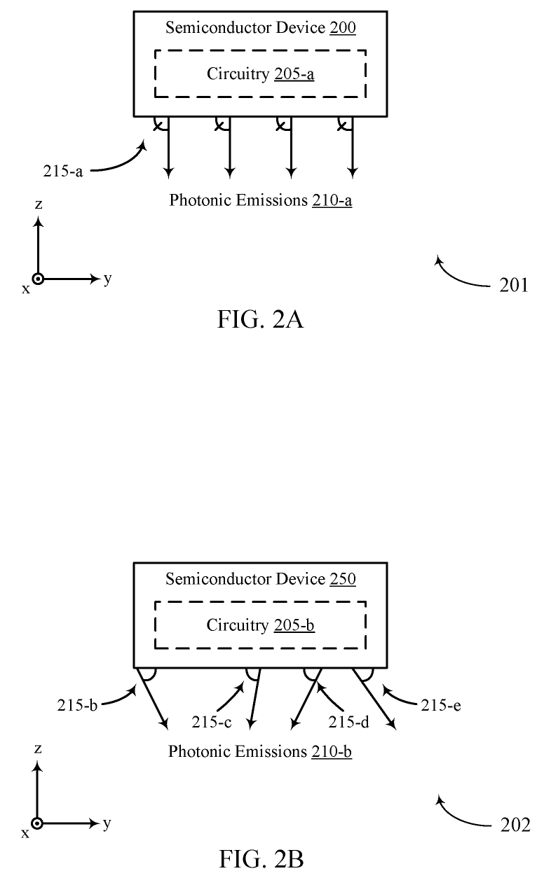

FIGS. 2A and 2B show examples of photonic emission diagrams 201 and 202, respectively, that support protection of semiconductor devices from optical scanning in accordance with examples as disclosed herein. The photonic emission diagrams 201 and 202 may illustrate aspects of a semiconductor device of a system 100 or component thereof (e.g., of a host system 105, of a processor 125, of a host system controller 120, of a memory system 110, of a memory device 145, of a local controller 150, of one or more memory arrays 155). For example, the photonic emission diagram 201 illustrates photonic emissions 210-a from a semiconductor device 200, and the photonic emission diagram 202 illustrates photonic emissions 210-b from a semiconductor device 250. Aspects of the photonic emission diagrams 201 and 202 may be described with reference the illustrated coordinate systems. For example, the photonic emission diagrams 201 and 202 illustrate aspects in an xz-plane, where components or aspects of the semiconductor devices 200 and 250 may extend some distance along the y-direction (e.g., into the page).

The photonic emission diagram 201 illustrates a semiconductor device 200 that includes circuitry 205-a. The circuitry 205-a may support memory operations, processing operations, or both, among other operations. In some cases, the circuitry 205-a may generate photonic emissions 210-a (e.g., during internal operations of the semiconductor device 200, based on current flow through the circuitry 205-a, based on switching of the circuitry 205-a). In some such examples, the photonic emissions 210-a may be measured to perform adverse analysis of the semiconductor device 200, or operations thereof.

In some cases, the semiconductor device 200 may be evaluated by a scanning technology (e.g., an optical scan) configured to determine information about the semiconductor device 200 based on the photonic emissions 210-a from the semiconductor device 200. For example, the scanning technology may analyze the photonic emissions 210-a to determine sources of the photonic emissions 210-a that may be within the circuitry 205-a. In some examples, based on an angle 215-a (e.g., an emission angle, relative to a surface of the semiconductor device 200, a common angle without differential refraction, an angle associated with coherent emissions), the scanning technology may determine the sources of the photonic emissions 210-a, which may be used to identify features of the circuitry 205-a, data stored in the circuitry 205-a, data access patterns, or operational characteristics of the semiconductor device 200. In some examples, the scanning technology may be supported by transmitting one or more wavelengths (e.g., in a range of 800 nm to 1600 nm, along the z-direction) to the semiconductor device 200 from a light producing source (e.g., a laser, external to the semiconductor device 200), and the semiconductor device 200 may convey or reflect the transmitted wavelength(s) to a measurement device of the scanning technology.

In some cases, if the photonic emissions 210-a are emitted or reflected from the semiconductor device 200 at a same angle 215-a (e.g., at a coherent angle, as a coherent emission, which may be perpendicular to a surface of the semiconductor device 200), the scanning technology may be able to trace the photonic emissions 210-a to the sources of the photonic emissions 210-a (e.g., within the circuitry 205). In some such examples, the scanning technology may determine data stored at or conveyed by the sources of the photonic emissions 210-a based on a strength, quality, or wavelength of the photonic emissions 210-a. In some such cases, the scanning technology may identify information that adversely affects security of the semiconductor device 200, or operations thereof, based on the photonic emissions 210-a.

The photonic emission diagram 202 illustrates a semiconductor device 250, which may be configured to refract photonic emissions 210-b (e.g., differentially refract, refract incoherently, as a non-coherent emission), which may impair an ability of a scanning technology to evaluate the semiconductor device 250. For example, the semiconductor device 250 may include or more material layers configured to refract photonic emissions 210-b emitted by circuitry 205-b. The material layer(s) may be positioned at one or more levels within the semiconductor device 250 and may include a configuration that supports refraction of the photonic emissions 210-b, which may prevent a scanning technology from tracing photonic emissions 210-b to sources of the photonic emissions 210-b (e.g., in the circuitry 205-b). For example, the material layer(s) may include geometric structures (e.g., surfaces, projections, cavities, irregularities), formed by manufacturing techniques (e.g., deposition, etching, ablation, fouling), that support refracting the photonic emissions 210-b at different angles 215 (e.g., angle 215-b, angle 215-c, angle 215-d, angle 215-e). Additionally, or alternatively, the material layer(s) include different doping configurations (e.g., associated with different refractive indexes) that support refracting the photonic emissions 210-b at different angles 215. Additionally, or alternatively, the material layer(s) may include particles (e.g., beads, spherical particles, ellipsoid particles, particles with irregular geometry) distributed in a material layer that support refracting the photonic emissions 210-b at different angles 215.

Refracting photonic emissions 210-b for emission at different angles 215 may prevent a scanning technology from evaluating the semiconductor device 250 (e.g., from evaluating the circuitry 205-b), or operations thereof (e.g., access operations, storage operations). For example, the material layer(s) may support refracting (e.g., changing propagation orientations of photonic emissions), diffusing (e.g., splitting or spreading propagation), or scattering (e.g., breaking up coherence of) the photonic emissions 210-b, such that various portions of the semiconductor device 250 may emit photonic emissions 210-b at the different angles 215. For example, portions of photonic emissions 210-b (e.g., from a given source, from multiple sources) may be emitted at different angles 215. In some cases, photonic emissions 210-b may be refracted based on a wavelength of the photonic emissions 210-b. For example, photonic emissions 210-b may be refracted for wavelengths in a range of 800 nm to 1600 nm, which may align with wavelengths of emission from the circuitry 205-b, or align with wavelengths of a scanning technology, or both. Thus, because a scanning technology may be unable to determine sources of photonic emissions 210-b, the semiconductor device 250 may benefit from improved security against adverse analysis by the scanning technology, among other benefits.

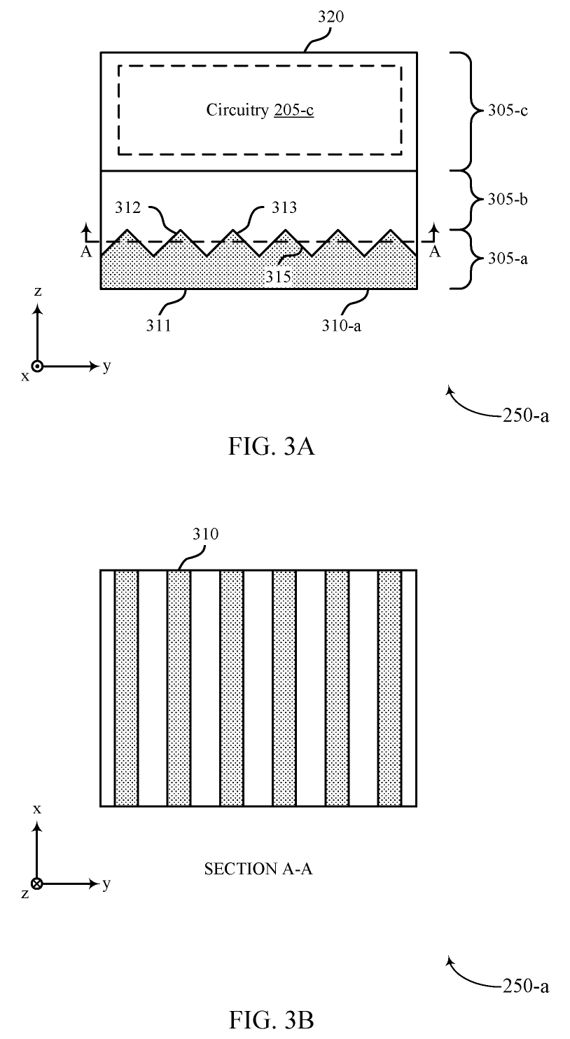

FIGS. 3A and 3B show an example of a semiconductor device 250-a that supports protection of semiconductor devices from optical scanning in accordance with examples as disclosed herein. The semiconductor device 250-a may be configured to refract photonic emissions, such that the semiconductor device 250-a may not be adversely analyzed by a scanning technology. Aspects of the semiconductor device 250-a may be described with reference to the illustrated coordinate system. For example, FIG. 3A illustrates the semiconductor device 250-a in a yz-plane, and FIG. 3B illustrates the semiconductor device 250-a in an xy-plane (e.g., as a cross-section along a section plane A-A).

The semiconductor device 250-a may include circuitry 205-c, which may be electronic circuitry such as one or more controllers or processors, complementary metal-oxide semiconductor (CMOS) circuitry, access circuitry (e.g., sense amplifiers, column decoders, row decoders), memory array circuitry (e.g., memory cells, access lines), or other circuitry configured to support processing operations, memory operations, or both. The semiconductor device 250-a may include one or more dies 320 (e.g., semiconductor dies, a single die, a stack of dies, an assembly of dies), each of which may include at least a portion of the circuitry 205-c. In some implementations, the die(s) 320 may include one or more memory dies including one or more arrays of memory cells.

The semiconductor device 250-a may include a stack of materials, and the stack of materials may be associated with multiple levels 305 (e.g., level 305-a, level 305-b, level 305-c, each associated with one or more layers of material). In some cases, each level 305 may include circuitry (e.g., of one or more dies 320) or structures associated with facilitating operations of the semiconductor device 250-a. For example, a level 305-c may include circuitry 205-c (e.g., of the one or more dies 320). In some such examples, a level 305-b may include a substrate (e.g., a semiconductor substrate, a silicon substrate, an assembly substrate, a material substrate) upon which other components of the semiconductor device 250-a (e.g., at least a portion of circuitry 205-c) are formed. In some implementations, at least some of the circuitry 205-c may be implemented within the level 305-b to support (e.g., physically, operationally) the die(s) 320. The level 305-a may include one or more material layers 310-a configured to refract (e.g., reflect, diffuse, disperse, scatter, break up coherence of) photonic emissions associated with the semiconductor device 250-a. In some cases, the substrate may be associated with a backside of the semiconductor device 250-a (e.g., a back side of a semiconductor substrate), and the material layer(s) 310-a may be implemented at the level 305-a based on the material layer(s) 310-a being formed adjacent to the backside of the semiconductor device 250-a. In some implementations, the material layer(s) 310-a may be implemented at the level 305-b and the substrate may be implemented at the level 305-a to prevent material layer(s) 310-a from being etched off the semiconductor device 250-a. In some cases, material layer(s) 310-a may be implemented at the level 305-a based on the level 305-c being associated with electrical contacts of the semiconductor device 250-a. Additionally, or alternatively, material layer(s) 310-a may be implemented at the level 305-a based on the level 305-a being associated with electrical contacts of the semiconductor device 250-a. In some cases, material layer(s) 310-a may extend along the z-direction as an interface between the level 305-a and the level 305-b.

The material layer(s) 310-a may include geometric structures 315. The geometric structures 315 may support refraction of photonic emissions 210-b based on the configuration of the geometric structures 315. For example, material layer(s) 310-a may be associated with different refractive indexes, including refractive indexes different from one or more other layers 310-a, different from levels 305-b or 305-c, or both. In some such examples, the geometric structures may thus refract photonic emissions 210-b along different angles based on different features of the geometric structures 315 being aligned along different directions. In some cases, a first set of the geometric structures 315 may be associated with a respective refracted angle (e.g., a respective angle 215) of the photonic emissions 210-b and another set of the geometric structures 315 may be associated with a different refracted angle of the photonic emissions 210-b. For example, the geometric structures 315 may include a first set of surfaces 312 having a first angle relative to a surface 311 of the semiconductor device 250-a, and a second set of surfaces 313 having a second angle relative to the surface 311 (among other quantities of different surfaces at different relative angles).

Geometric structures 315 may support multiple angles based on different sets of surfaces being associated with various profiles. For example, sets of surfaces may form one or more serrated profiles, one or more stepped profiles, one or more contoured profiles, one or more parabolic profiles, or any combination thereof. As illustrated in FIG. 3A, geometric structures 315 may include a symmetrical serrated profile along material layer(s) 310-a, though a varying or random serrated profile may be implemented for further dispersion of photonic emissions 210-b. As illustrated in FIG. 3A, geometric structures 315 may include a first set of surfaces 312 at a 45 degree angle relative to the surface 311, and a second set of surfaces 313 at a -45 degree angle (e.g., a 135 degree angle) relative to the surface 311. However, in some other cases, at least some geometric structures 315 may include one or more sets of surfaces at angles between 35 degrees and 55 degrees, between -35 degrees and -55 degrees, or both relative to the surface 311. In some cases, at least some geometric structures 315 may implement a profile with a repetition dimension less than quarter of a wavelength of interest, such as a quarter wavelength of photonic emissions in a range of 800 nm to 1600 nm wavelength. For example, at least some geometric structures 315 may implement a profile with a pitch dimension of 200 nm or less. However, in some other cases, at least some geometric structures 315 may implement a profile with a variable pitch dimension. In some cases, at least some geometric structures 315 may be configured with a profile forming one or more Fresnel lens configurations (e.g., one or more focal points), which may focus photonic emissions 210-b to or from one or more configured locations.

A semiconductor device 250-a may be formed with material layer(s) 310-a in various manners for refracting the photonic emissions 210-b from circuitry 205-c. In some cases, forming a semiconductor device 250-a may include forming die(s) 320 including circuitry 205-c (e.g., above a substrate, along the z-direction). For example, forming a semiconductor device 250-a may include forming (e.g., or providing) a substrate at the level 305-b and forming the circuitry 205-c above the substrate at level 305-c. In some such examples, before or after forming the circuitry 205-c, one or more material layers 310-a may be formed. In some examples, material layer(s) 310-a may be formed at the level 305-a below the substrate at the level 305-b. Additionally, or alternatively, material layer(s) 310-a may be formed during formation of one or more dies 320 or the circuitry 205-c. For example, die(s) 320 or circuitry 205-c may be formed at the level 305-c, and material layer(s) 310-a may be formed at the level 305-b.

In some cases, forming material layer(s) 310-a may include depositing or removing portions of one or more materials associated with the material layer(s) 310-a. For example, forming material layer(s) 310-a may include forming a base layer and forming the geometric structures 315 at an interface of the base layer. In some examples, a base layer may be formed with a first material (e.g., with first surfaces of geometric structures 315 of the first material), then a second material may be deposited above the base layer at the interface to form the geometric structures 315 (e.g., with corresponding surfaces of geometric structures 315 of the second material). In some implementations, a material deposited above a base layer to form the geometric structures 315 may be a same material or a different material from the base layer. In other examples, the base layer may be formed then material may be removed from the interface of the base layer to form the geometric structures 315. For example, a laser may be applied to a material layer 310-a (e.g., to a base layer, with a laser having a relatively low wavelength that does not penetrate the base layer), which may include applying a laser to a semiconductor substrate of the semiconductor device 250-a (e.g., a back side of the substrate). In some implementations, such techniques may be implemented to inexpensively etch a random pattern onto the backside to provide such countermeasures. In some other examples, such surfaces may be provided by a “dirty” process, or by an operation that shoots another material at the surface, that disturbs the surface (e.g., causes the surfaces to have irregularities that support differential refraction). In some such examples, after removing material from the base layer, another material may be added to the base layer to form the geometric structures, which may be different from the material of the base layer.

Implementing one or more material layers 310-a with geometric structures 315 within the semiconductor device 250-a may support refraction of the photonic emissions from the semiconductor device 250-a. For example, material layer(s) 310-a may refract photonic emissions from the circuitry 205-c during a scanning operation on the semiconductor device 250-a. In some such examples, because the photonic emissions are refracted, the scanning operation may not determine information for adverse analysis of the semiconductor device 250-a, which may improve security of the semiconductor device 250-a.

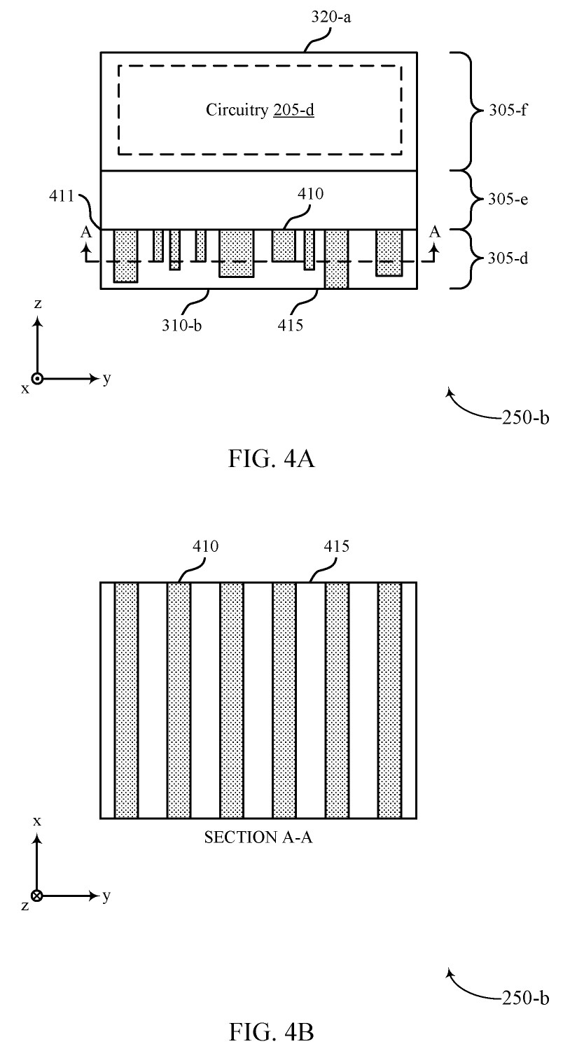

FIGS. 4A and 4B show an example of a semiconductor device 250-b that supports protection of semiconductor devices from optical scanning in accordance with examples as disclosed herein. The semiconductor device 250-b may be configured to refract photonic emissions, such that the semiconductor device 250-b may not be adversely analyzed by a scanning technology. Aspects of the semiconductor device 250-b may be described with reference to the illustrated coordinate system. For example, FIG. 4A illustrates the semiconductor device 250-b in a yz-plane, and FIG. 4B illustrates the semiconductor device 250-b in an xy-plane (e.g., as a cross-section along a section plane A-A).

The semiconductor device 250-b may include circuitry 205-d, which may be electronic circuitry such as one or more controllers or processors, complementary metal-oxide semiconductor (CMOS) circuitry, access circuitry (e.g., sense amplifiers, column decoders, row decoders), memory array circuitry (e.g., memory cells, access lines), or other circuitry configured to support processing operations, memory operations, or both. The semiconductor device 250-b may include one or more dies 320-a (e.g., semiconductor dies, a single die, a stack of dies, an assembly of dies), each of which may include at least a portion of the circuitry 205-d. In some implementations, the die(s) 320 may include one or more memory dies including one or more arrays of memory cells.

The semiconductor device 250-b may include a stack of materials, and the stack of materials may be associated with multiple levels 305 (e.g., level 305-d, level 305-e, level 305-f). In some cases, each level 305 may include circuitry (e.g., of one or more dies 320-a) or structures associated with the semiconductor device 250-b. For example, the level 305-e may include a substrate, and the level 305-f may include circuitry 205-d formed at least in part above the substrate. The level 305-d may include one or more material layers 310-b (e.g., as an alternative to layer(s) 310-a, in addition to layers 310-a, not shown) configured to refract (e.g., reflect, diffuse, disperse, scatter, break up coherence of) photonic emissions 210-b associated with the semiconductor device 250-b (e.g., from the circuitry 205-d). Additionally, or alternatively, material layer(s) 310-b may be implemented at the level 305-e and the substrate may be implemented at the level 305-d, or material layer(s) 310-b may be implemented above a level 305-f (e.g., above circuitry 205-d), among other implementations.

The material layer(s) 310-b may include portions having different doping configurations that support refraction of photonic emissions 210-b based on the different doping configurations. For example, portions of the material layer(s) 310-b (e.g., the different doping configurations) may be associated with different refractive indexes, including refractive indexes different from each other, different from one or more other layers 310, different from levels 305-e or 305-f, or both. In some such examples, the different doping configurations of the material layer may refract photonic emissions 210-b along different angles based on different doping configurations being located at various positions of the material layer(s) 310-b, having different geometries, or both.

In some cases, material layer(s) 310-b may include a set of one or more first portions 410 having a first doping configuration and a set of one or more second portions 415 having a second doping configuration with a different refractive index than the first portion(s) 410. In some such cases, the first portion(s) 410 may be associated with one or more first refracted angles (e.g., angle(s) 215) of photonic emissions 210-b and the set of second portions 415 may be associated with different refracted angle(s) of the photonic emissions 210-b. In some cases, a doping configuration of first portion(s) 410, second portion(s) 415, or both may include doping into or through a material layer 310-b (e.g., along the z-direction).

In some examples, first portions 410 and second portions 415 may refer to portions of a material layer 310-b that have different concentrations of a dopant. For example, some portions of a material layer 310-b may include a greater concentration of a dopant and other portions may include a lower concentration of the dopant (e.g., greater than or equal to zero dopant). In some such cases, portions with a relatively higher concentration of a dopant may be associated with refracted angle(s) of photonic emissions 210-b and portions with a relatively lower concentration of the dopant may be associated with different refracted angle(s) of the photonic emissions 210-b.

Additionally, or alternatively, first portions 410 and second portions 415 may refer to portions of a material layer 310-b that have different types of dopant. For example, some portions of a material layer 310-b may include a first dopant (e.g., a first type of molecular doping, an n-type doping) and other portions may include a second dopant (e.g., a second type of molecular doping, a p-type doping) different from the first dopant. In some such cases, portions with a first dopant type may be associated with refracted angle(s) of photonic emissions 210-b and portions with a second doping type may be associated with different refracted angle(s) of the photonic emissions 210-b.

In some implementations, the doping configurations of a layer 310 may support multiple angles based on the doping configurations being associated with various profiles (e.g., in accordance with one or more depths along the z-direction, in accordance with one or more widths along the x-direction, along the y-direction, or both, curved profiles, straight profiles). In the example of FIGS. 4A and 4B, the doping configurations of the material layer 310-b may include the first portions 410 that are doped into an interface 411 of the level 305-d. In some examples, second portion(s) 415 may refer to portions of the layer 310-b that have a different doping configuration than first portion(s) 410, such as being undoped, doped with a different dopant concentration, or doped with a different dopant type, among other examples.

In some examples, the level 305-d may refer to a substrate (e.g., a semiconductor substrate, a semiconductor wafer), and the interface 411 may refer to a front side of the substrate. In some examples (not shown), at least a portion of the substrate of the level 305-d may be doped to form at least a portion of the circuitry 205-d (e.g., in which case first portions 410 and doped portions of the circuitry 205-d may be formed on a same side of a semiconductor substrate). Additionally, or alternatively, first portions 410 may be doped from a back side of a substrate (e.g., of a substrate that includes at least a portion of circuitry 205-d), or first portions 410 may be doped into a substrate that is different from a substrate from which circuitry 205-d is formed. In some examples, first portions 410 may include a different gradient of concentration of the dopants, or a same gradient of concentration of the dopants along the z-direction. In some cases, at least some doped portions (e.g., first portions 410, second portions 415, or both) may implement a profile with a repetition dimension less than quarter of a wavelength of interest, such as a quarter wavelength of photonic emissions in a range of 800 nm to 1600 nm wavelength. For example, at least some doped portions may implement a profile with a pitch dimension of 200 nm or less. However, in some other cases, at least some doped portions may implement a profile with a variable pitch dimension. In some cases, at least some doped portions may be configured with a profile forming one or more Fresnel lens configurations (e.g., one or more focal points), which may focus photonic emissions 210-b to or from one or more configured locations.

A semiconductor device 250-b may be formed with material layer(s) 310-b in various manners for refracting the photonic emissions 210-b from circuitry 205-d. In some cases, forming a semiconductor device 250-b may include forming die(s) 320-a including circuitry 205-d (e.g., above a substrate, along the z-direction). For example, forming a semiconductor device 250-b may include forming (e.g., or providing) a substrate at the level 305-e and forming the circuitry 205-d above the substrate at level 305-e. In some such examples, before or after forming the circuitry 205-d, one or more material layers 310-b may be formed. In some examples, material layer(s) 310-b may be formed at the level 305-d below the substrate at the level 305-e. Additionally, or alternatively, material layer(s) 310-b may be formed during formation of one or more dies 320-a or the circuitry 205-d. For example, die(s) 320-a or circuitry 205-d may be formed at the level 305-f, and material layer(s) 310-b may be formed at the level 305-e.

In some cases, forming material layer(s) 310-b may include doping portions of one or more materials associated with the material layer(s) 310-b. For example, forming material layer(s) 310-b may include forming a base layer and doping the base layer from the interface 411 along the z-direction. In some examples, a base layer may be formed, then a mask may be formed above the base layer and the dopant may be applied to the base layer. The mask may prevent covered portions of the base layer from being doped, while uncovered portions of the base layer are doped with the dopant. In some cases, masking may facilitate forming first portions 410 and the second portions 415. Likewise, masking may facilitate forming differently doped portions, different type doped portions, different concentrations of the dopant among the portions, or any combination thereof.

Implementing one or more material layers 310-b with first portions 410 and second portions 415 within the semiconductor device 250-b may support refraction of the photonic emissions from the semiconductor device 250-b. For example, material layer(s) 310-b may refract photonic emissions from the circuitry 205-d during a scanning operation on the semiconductor device 250-b. In some such examples, because the photonic emissions are refracted, the scanning operation may not determine information for adverse analysis of the semiconductor device 250-b, which may improve security of the semiconductor device 250-b.

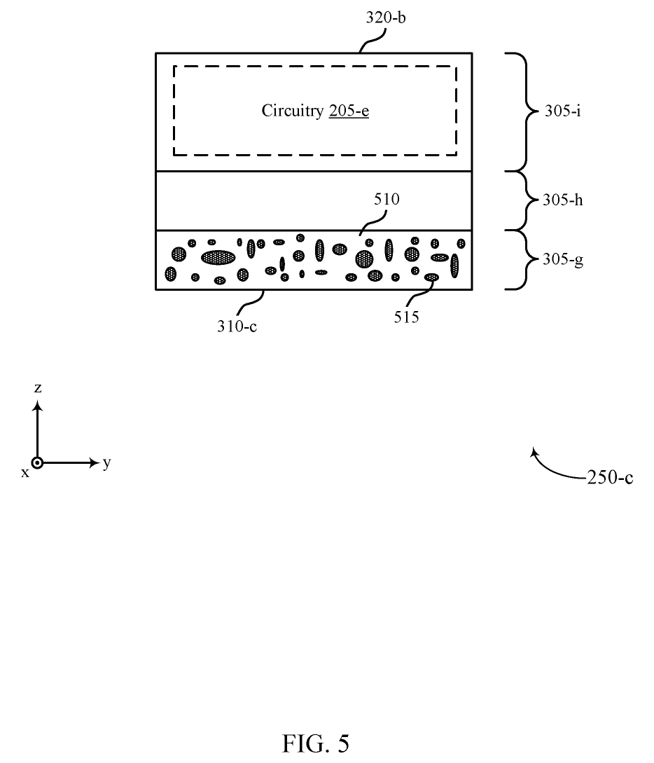

FIG. 5 shows an example of a semiconductor device 250-c that supports protection of semiconductor devices from optical scanning in accordance with examples as disclosed herein. The semiconductor device 250-c may be configured to refract photonic emissions, such that the semiconductor device 250-c may not be adversely analyzed by a scanning technology. Aspects of the semiconductor device 250-c may be described with reference to the illustrated coordinate system. For example, FIG. 5 illustrates the semiconductor device 250-c in a yz-plane.

The semiconductor device 250-c may include circuitry 205-e, which may be electronic circuitry such as one or more controllers or processors, complementary metal-oxide semiconductor (CMOS) circuitry, access circuitry (e.g., sense amplifiers, column decoders, row decoders), memory array circuitry (e.g., memory cells, access lines), or other circuitry configured to support processing operations, memory operations, or both. The semiconductor device 250-c may include one or more dies 320-b (e.g., semiconductor dies, a single die, a stack of dies, an assembly of dies), each of which may include at least a portion of the circuitry 205-e. In some implementations, the die(s) 320 may include one or more memory dies including one or more arrays of memory cells.

The semiconductor device 250-c may include a stack of materials, and the stack of materials may be associated with multiple levels 305 (e.g., level 305-g, level 305-h, level 305-i). In some cases, each level 305 may include circuitry (e.g., of one or more dies 320-b) or structures associated with the semiconductor device 250-c. For example, the level 305-h may include a substrate, and the level 305-i may include circuitry 205-e formed at least in part above the substrate. The level 305-g may include one or more material layers 310-c (e.g., as an alternative to material layer(s) 310-a and/or 310-b, in addition to material layers 310-a and/or 310-b, not shown) configured to refract (e.g., reflect, diffuse, disperse, scatter, break up coherence of) photonic emissions 210-b associated with the semiconductor device 250-c (e.g., from the circuitry 205-e). Additionally, or alternatively, material layer(s) 310-c may be implemented at the level 305-h and the substrate may be implemented at the level 305-g, or material layer(s) 310-c may be implemented above a level 305-i (e.g., above circuitry 205-e), among other implementations.

The material layer(s) 310-c may include particles 515 embedded in a base material 510 (e.g., geometric structures associated with the material layer(s) 310-c) that support refraction of photonic emissions 210-b. In some examples, a base material 510 may be a first material and particles 515 may be one or more second materials that are different from the first material. In some examples, a base material 510 and particles 515 may be associated with different refractive indexes, including refractive indexes different from each other, different from one or more other material layers 310, different from levels 305-h or 305-i, or both. In some examples, a base material 510 may be transparent (e.g., transmissive) to photonic emissions 210-b and particles 515 may be opaque (e.g., non-transmissive) to photonic emissions 210-b. In some such examples, the particles 515 and base material 510 may refract photonic emissions 210-b along different angles based on particles 515 being located at various positions of the material layer(s) 310-c, having different geometries (e.g., shapes, sizes, aspect ratios), or both.

A semiconductor device 250-c may be formed with material layer(s) 310-c in various manners for refracting the photonic emissions 210-b from circuitry 205-e. In some cases, forming a semiconductor device 250-c may include forming die(s) 320-b including circuitry 205-e (e.g., above a substrate, along the z-direction). For example, forming a semiconductor device 250-c may include forming (e.g., or providing) a substrate at the level 305-h and forming the circuitry 205-e above the substrate at level 305-h. In some such examples, before or after forming the circuitry 205-e, one or more material layers 310-c may be formed. In some examples, material layer(s) 310-c may be formed at the level 305-g below the substrate at the level 305-h. Additionally, or alternatively, material layer(s) 310-c may be formed during formation of one or more dies 320-b or the circuitry 205-e. For example, die(s) 320-b or circuitry 205-e may be formed at the level 305-i, and material layer(s) 310-c may be formed at the level 305-h.

In some examples, a base material 510 may be selected to be opaque to photonic emissions 210-b (e.g., not transparent to near-infrared radiation), with or without particles 515, which may be implemented alone or in combination with one or more other layers (e.g., any of material layers 310-a through 310-c). In some such examples, one or more material layers 310-c may be formed (e.g., applied, injected, coated) in a level 305-h before a substrate is doped to form a portion of the circuitry 205-e, and the substrate (e.g., silicon) may be regrown (e.g., epitaxially or otherwise), such that a material layer 310-c may be embedded in a substrate, which may prevent efforts to remove the layer 310-c (e.g., by plasma etching) to permit adverse analysis. Additionally, or alternatively, a layer 310 (e.g., any of layers 310-a through 310-c) may include a logo etched or stamped obfuscation of coating.

Implementing one or more material layers 310-c with a base material 510 (e.g., and particles 515) within the semiconductor device 250-c may support refraction of the photonic emissions from the semiconductor device 250-c. For example, material layer(s) 310-c may refract photonic emissions from the circuitry 205-e during a scanning operation on the semiconductor device 250-c. In some such examples, because the photonic emissions are refracted, the scanning operation may not determine information for adverse analysis of the semiconductor device 250-c, which may improve security of the semiconductor device 250-c.

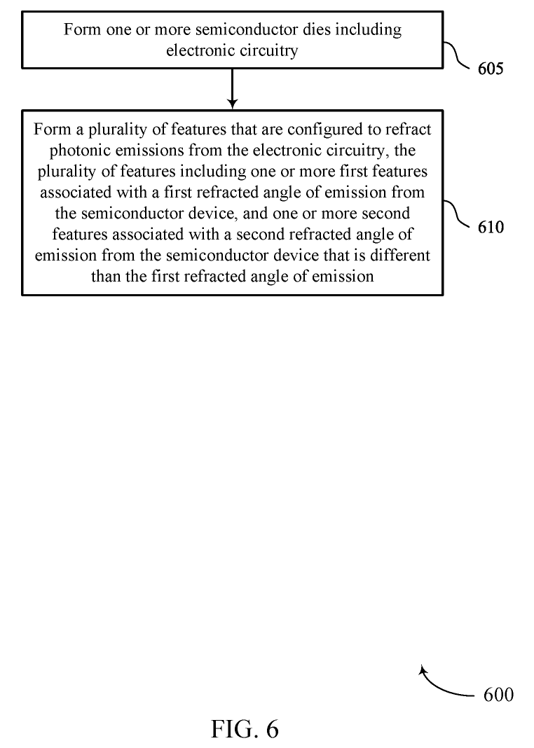

FIG. 6 shows a flowchart illustrating a method or methods 600 that supports protection of semiconductor devices from optical scanning in accordance with examples as disclosed herein. The operations of method 600 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 605, the method may include forming one or more semiconductor dies including electronic circuitry.

At 610, the method may include forming a plurality of features that are configured to refract photonic emissions from the electronic circuitry, the plurality of features including one or more first features associated with a first refracted angle of emission from the semiconductor device, and one or more second features associated with a second refracted angle of emission from the semiconductor device that is different from the first refracted angle of emission.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming one or more semiconductor dies including electronic circuitry; forming a plurality of features that are configured to refract photonic emissions from the electronic circuitry, the plurality of features including; one or more first features associated with a first refracted angle of emission from the semiconductor device; and one or more second features associated with a second refracted angle of emission from the semiconductor device that is different from the first refracted angle of emission.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 2: A semiconductor device, including: one or more semiconductor dies including electronic circuitry configured for accessing one or more memory arrays of the one or more semiconductor dies, configured for processing data, or a combination thereof; and one or more material layers stacked with the one or more semiconductor dies, each of the one or more material layers having a respective plurality of geometric structures that are configured to refract photonic emissions from the electronic circuitry.

Aspect 3: The semiconductor device of aspect 2, where, for each of the one or more material layers, the respective plurality of geometric structures include: one or more first geometric structures associated with a first refracted angle of emission from the semiconductor device; and one or more second geometric structures associated with a second refracted angle of emission from the semiconductor device.

Aspect 4: The semiconductor device of any of aspects 2 through 3, where, for each of the one or more material layers, the respective plurality of geometric structures include: one or more first surfaces along a side of the material layer having a first angle relative to a surface of the semiconductor device; and one or more second surfaces along the side of the material layer having a second angle relative to the surface of the semiconductor device.

Aspect 5: The semiconductor device of aspect 4, where, for at least one of the one or more material layers, the one or more first surfaces and the one or more second surfaces are associated with one or more serrated profiles, one or more stepped profiles, one or more contoured profiles, one or more parabolic profiles, or a combination thereof.

Aspect 6: The semiconductor device of any of aspects 2 through 5, where, for at least one of the one or more material layers, the respective plurality of geometric structures is associated with an interface between the material layer and another material layer of the semiconductor device.

Aspect 7: The semiconductor device of aspect 6, where: the at least one of the one or more material layers is associated with a first refractive index; and the other material layer of the semiconductor device is associated with a second refractive index that is different from the first refractive index.

Aspect 8: The semiconductor device of any of aspects 6 through 7, where the other material layer of the semiconductor device is associated with a semiconductor substrate of one of the one or more semiconductor dies.

Aspect 9: The semiconductor device of any of aspects 6 through 8, where the other material layer of the semiconductor device is a second of the one or more material layers stacked with the one or more semiconductor dies.

Aspect 10: The semiconductor device of any of aspects 2 through 9, where, for at least one of the one or more material layers, the respective plurality of geometric structures is associated with particles embedded in a base material.

Aspect 11: The semiconductor device of any of aspects 2 through 10, where at least one of the one or more material layers is positioned on an opposite side of the electronic circuitry as a set of one or more electrical contacts of the semiconductor device.

Aspect 12: The semiconductor device of any of aspects 2 through 11, where at least one of the one or more material layers is positioned on a same side of the electronic circuitry as a set of one or more electrical contacts of the semiconductor device.

Aspect 13: The semiconductor device of any of aspects 2 through 12, where, for at least one of the one or more material layers, the respective plurality of geometric structures is configured to refract photonic emissions with wavelengths in a range of 800 nm to 1600 nm.

Aspect 14: The semiconductor device of any of aspects 2 through 13, where, for at least one of the one or more material layers, at least one of the respective plurality of geometric structures is associated with a surface of the material layer having an angle, relative to a substrate of the one or more semiconductor dies, that is between 35 and 55 degrees.

Aspect 15: The semiconductor device of any of aspects 2 through 14, where, for at least one of the one or more material layers, the respective plurality of geometric structures is configured in accordance with a pitch dimension of 200 nm or less.

Aspect 16: The semiconductor device of any of aspects 2 through 15, where, for at least one of the one or more material layers, the respective plurality of geometric structures is configured in accordance with a variable pitch dimension.

Aspect 17: The semiconductor device of any of aspects 2 through 16, where, for at least one of the one or more material layers, the respective plurality of geometric structures is configured in accordance with one or more Fresnel lens configurations.

An apparatus is described. The following provides an overview of aspects of the apparatus as described herein:

Aspect 18: A semiconductor device, including: one or more semiconductor dies including electronic circuitry configured for accessing one or more memory arrays of the one or more semiconductor dies, configured for processing data, or a combination thereof; and one or more material layers stacked with the one or more semiconductor dies and configured to refract photonic emissions from the electronic circuitry, where each of the one or more material layers includes a respective plurality of first portions having a first doping configuration and a respective plurality of second portions having a second doping configuration with a different refractive index than the first doping configuration.

Aspect 19: The semiconductor device of aspect 18, where, for at least one of the one or more material layers: the respective plurality of first portions are associated with a first refracted angle of emission from the semiconductor device; and the respective plurality of second portions are associated with a second refracted angle of emission from the semiconductor device.

Aspect 20: The semiconductor device of any of aspects 18 through 19, where at least one of the one or more material layers is associated with a layer of a semiconductor substrate of one of the one or more semiconductor dies opposite electronic circuitry of the one of the one or more semiconductor dies.

Aspect 21: The semiconductor device of any of aspects 18 through 20, where at least one of the one or more material layers is positioned on an opposite side of the electronic circuitry as a set of one or more electrical contacts of the semiconductor device.

Aspect 22: The semiconductor device of any of aspects 18 through 21, where, for at least one of the one or more material layers, the respective plurality of first portions and the respective plurality of second portions alternate along the material layer in accordance with a pitch dimension of 200 nm or less.

Aspect 23: The semiconductor device of any of aspects 18 through 22, where, for at least one of the one or more material layers, the respective plurality of first portions and the respective plurality of second portions alternate along the material layer in accordance with a variable pitch dimension.

Aspect 24: The semiconductor device of any of aspects 18 through 23, where at least one of the one or more material layers is positioned on a same side of the electronic circuitry as a set of one or more electrical contacts of the semiconductor device.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “isolated” may refer to a relationship between components in which signals are not presently capable of flowing between the components. Components are isolated from each other if there is an open circuit between them. For example, two components separated by a switch that is positioned between the components are isolated from each other when the switch is open. When a component isolates two components, the component may initiate a change that prevents signals from flowing between the other components using a conductive path that previously permitted signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorous, boron, or arsenic.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A semiconductor device, comprising:
one or more semiconductor dies comprising electronic circuitry configured for accessing one or more memory arrays of the one or more semiconductor dies, configured for processing data, or a combination thereof; and
one or more material layers stacked with the one or more semiconductor dies, each of the one or more material layers having a respective plurality of geometric structures that are configured to refract photonic emissions from the electronic circuitry.

2. The semiconductor device of claim 1, wherein, for each of the one or more material layers, the respective plurality of geometric structures comprise:
one or more first geometric structures associated with a first refracted angle of emission from the semiconductor device; and
one or more second geometric structures associated with a second refracted angle of emission from the semiconductor device.

3. The semiconductor device of claim 1, wherein, for each of the one or more material layers, the respective plurality of geometric structures comprise:
one or more first surfaces along a side of the material layer having a first angle relative to a surface of the semiconductor device; and
one or more second surfaces along the side of the material layer having a second angle relative to the surface of the semiconductor device.

4. The semiconductor device of claim 3, wherein for at least one of the one or more material layers, the one or more first surfaces and the one or more second surfaces are associated with one or more serrated profiles, one or more stepped profiles, one or more contoured profiles, one or more parabolic profiles, or a combination thereof.

5. The semiconductor device of claim 1, wherein for at least one of the one or more material layers, the respective plurality of geometric structures is associated with an interface between the material layer and another material layer of the semiconductor device.

6. The semiconductor device of claim 5, wherein:
the at least one of the one or more material layers is associated with a first refractive index; and
the other material layer of the semiconductor device is associated with a second refractive index that is different from the first refractive index.

7. The semiconductor device of claim 5, wherein the other material layer of the semiconductor device is associated with a semiconductor substrate of one of the one or more semiconductor dies.

8. The semiconductor device of claim 5, wherein the other material layer of the semiconductor device is a second of the one or more material layers stacked with the one or more semiconductor dies.

9. The semiconductor device of claim 1, wherein for at least one of the one or more material layers, the respective plurality of geometric structures is associated with particles embedded in a base material.

10. The semiconductor device of claim 1, wherein at least one of the one or more material layers is positioned on an opposite side of the electronic circuitry as a set of one or more electrical contacts of the semiconductor device.

11. The semiconductor device of claim 1, wherein at least one of the one or more material layers is positioned on a same side of the electronic circuitry as a set of one or more electrical contacts of the semiconductor device.

12. The semiconductor device of claim 1, wherein for at least one of the one or more material layers, the respective plurality of geometric structures is configured to refract photonic emissions with wavelengths in a range of 800 nm to 1600 nm.

13. The semiconductor device of claim 1, wherein for at least one of the one or more material layers, at least one of the respective plurality of geometric structures is associated with a surface of the material layer having an angle, relative to a substrate of the one or more semiconductor dies, that is between 35 and 55 degrees.

14. The semiconductor device of claim 1, wherein for at least one of the one or more material layers, the respective plurality of geometric structures is configured in accordance with a pitch dimension of 200 nm or less.

15. The semiconductor device of claim 1, wherein for at least one of the one or more material layers, the respective plurality of geometric structures is configured in accordance with a variable pitch dimension.

16. The semiconductor device of claim 1, wherein for at least one of the one or more material layers, the respective plurality of geometric structures is configured in accordance with one or more Fresnel lens configurations.

17. A semiconductor device, comprising:
one or more semiconductor dies comprising electronic circuitry configured for accessing one or more memory arrays of the one or more semiconductor dies, configured for processing data, or a combination thereof; and
one or more material layers stacked with the one or more semiconductor dies and configured to refract photonic emissions from the electronic circuitry, wherein each of the one or more material layers comprises a respective plurality of first portions having a first doping configuration and a respective plurality of second portions having a second doping configuration with a different refractive index than the first doping configuration.

18. The semiconductor device of claim 17, wherein, for at least one of the one or more material layers:
the respective plurality of first portions are associated with a first refracted angle of emission from the semiconductor device; and
the respective plurality of second portions are associated with a second refracted angle of emission from the semiconductor device.

19. The semiconductor device of claim 17, wherein at least one of the one or more material layers is associated with a layer of a semiconductor substrate of one of the one or more semiconductor dies opposite electronic circuitry of the one of the one or more semiconductor dies.

20. The semiconductor device of claim 17, wherein at least one of the one or more material layers is positioned on an opposite side of the electronic circuitry as a set of one or more electrical contacts of the semiconductor device.

21. The semiconductor device of claim 17, wherein for at least one of the one or more material layers, the respective plurality of first portions and the respective plurality of second portions alternate along the material layer in accordance with a pitch dimension of 200 nm or less.

22. The semiconductor device of claim 17, wherein for at least one of the one or more material layers, the respective plurality of first portions and the respective plurality of second portions alternate along the material layer in accordance with a variable pitch dimension.

23. The semiconductor device of claim 17, wherein at least one of the one or more material layers is positioned on a same side of the electronic circuitry as a set of one or more electrical contacts of the semiconductor device.

24. A method of forming a semiconductor device, comprising:
forming one or more semiconductor dies comprising electronic circuitry; and
forming a plurality of features that are configured to refract photonic emissions from the electronic circuitry, the plurality of features comprising:
one or more first features associated with a first refracted angle of emission from the semiconductor device; and
one or more second features associated with a second refracted angle of emission from the semiconductor device that is different from the first refracted angle of emission.
